(19) United States
(12) Patent Application Publication
(10) Pub. No.: US 2024/0249960 A1
(43) Pub. Date: Jul. 25, 2024

(54) SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: KOKUSAI ELECTRIC CORPORATION, Tokyo (JP)

(72) Inventors: Kazuya NABETA, Toyama-shi (JP); Haruo MORIKAWA, Toyama-shi (JP); Yoshihiko YANAGISAWA, Toyama-shi (JP)

(73) Assignee: KOKUSAI ELECTRIC CORPORATION, Tokyo (JP)

(21) Appl. No.: 18/612,221

(22) Filed: Mar. 21, 2024

Related U.S. Application Data
(63) Continuation of application No. PCT/JP22/33171, filed on Sep. 2, 2022.

(30) Foreign Application Priority Data
Sep. 24, 2021 (JP) 2021-155954

(51) Int. Cl. H01L 21/67; H01L 21/02; H01L 21/673; H01L 21/687; H05B 6/64; H05B 6/74

(52) U.S. Cl. CPC H01L 21/67115; H01L 21/02345; H01L 21/67389; H01L 21/68771; H05B 6/6447; H05B 6/745

(57) ABSTRACT

There is provided a technique that includes: a process chamber in which a substrate is processed; a gas supplier configured to supply a gas into the process chamber; a microwave supplier configured to supply a microwave into the process chamber; and a microwave stirrer configured to stir the microwave by being rotated due to a flow of the gas in the process chamber.

### CROSS-REFERENCE TO RELATED PATENT APPLICATION

This application is a bypass continuation application of PCT International Application No. PCT/JP2022/033171, filed on Sep. 2, 2022, in the WIPO, the international application being based upon and claiming the benefit of priority from Japanese Patent Application No. 2021-155954, filed on Sep. 24, 2021, in the Japanese Patent Office, the entire contents of which are hereby incorporated by reference.

### FIELD

The present disclosure relates to a substrate processing apparatus, a substrate processing method, a method of manufacturing a semiconductor device and a non-transitory computer-readable recording medium.

### RELATED ART

As a part of a manufacturing process of a semiconductor device, a modification process such as an annealing process may be performed. Recently, the semiconductor device is integrated at a high density and remarkably miniaturized. As a result, it is preferable that the modification process is performed to obtain a substrate on which a high density pattern is formed with a high aspect ratio. According to some related arts, as the modification process for such a substrate, a microwave heating (which is a heat treatment process using a microwave) may be performed.

### SUMMARY

According to the present disclosure, there is provided a technique capable of preventing a uniformity of a temperature distribution on a substrate from deteriorating when a microwave heating is performed, and thereby capable of preventing a deterioration in a productivity of a substrate processing.

According to an aspect of the present disclosure, there is provided a technique that includes: a process chamber in which a substrate is processed; a gas supplier configured to supply a gas into the process chamber; a microwave supplier configured to supply a microwave into the process chamber; and a microwave stirrer configured to stir the microwave by being rotated due to a flow of the gas in the process chamber.

### BRIEF DESCRIPTION OF THE DRAWINGS

FIG. 1 is a diagram schematically illustrating a vertical cross-section of a substrate processing apparatus according to one or more embodiments of the present disclosure, when viewed from side.

FIG. 2 is a diagram schematically illustrating a horizontal cross-section of the substrate processing apparatus according to the embodiments of the present disclosure, when viewed from above.

FIG. 3 is a diagram schematically illustrating an enlarged cross-section of a process chamber of the substrate processing apparatus according to the embodiments of the present disclosure, when viewed from side.

FIG. 4 is a diagram schematically illustrating a perspective view of the process chamber of the substrate processing apparatus according to the embodiments of the present disclosure, when viewed from a transfer chamber of the substrate processing apparatus and when viewed from slightly above.

FIG. 5 is a diagram schematically illustrating an enlarged cross-section (taken along a line A-A of FIG. 4) of the process chamber of the substrate processing apparatus according to the embodiments of the present disclosure, when viewed from the transfer chamber.

FIG. 6 is a diagram schematically illustrating a cross-section of a microwave stirrer of the substrate processing apparatus according to the embodiments of the present disclosure, when viewed from side.

FIG. 7 is a block diagram schematically illustrating a configuration of a controller and related components of the substrate processing apparatus according to the embodiments of the present disclosure.

FIG. 8 is a flow chart schematically illustrating a substrate processing according to the embodiments of the present disclosure.

### DETAILED DESCRIPTION

### Embodiments of Present Disclosure

Hereinafter, one or more embodiments (also simply referred to as “embodiments”) of the technique of the present disclosure will be described in detail with reference to the drawings.

A substrate processing apparatus exemplified in the following description can be used in a manufacturing process of a semiconductor device, and is configured to perform a predetermined treatment process on a substrate to be processed. For example, a silicon wafer (hereinafter, also simply referred to as a “wafer”) may be used as the substrate to be processed. The silicon wafer may serve as a semiconductor substrate on which the semiconductor device is manufactured. Further, in the present specification, the term “wafer” may refer to “a wafer itself”, or may refer to “a wafer and a stacked structure (aggregated structure) of a predetermined layer (or layers) or a film (or films) formed on a surface of the wafer”. That is, the term “wafer” may collectively refer to “a wafer and layers or films formed on a surface of the wafer”. Further, in the present specification, the term “a surface of a wafer” may refer to “a surface (exposed surface) of a wafer itself”, or may refer to “a surface of a predetermined layer or a film formed on a wafer, i.e. a top surface (uppermost surface) of the wafer as a stacked structure”. In the present specification, the terms “substrate” and “wafer” may be used as substantially the same meaning. That is, the term “substrate” may be substituted by “wafer” and vice versa. For example, the predetermined treatment process (hereinafter, may also be simply referred to as “process”) performed on the wafer may include a process such as an annealing process (modification process), an oxidation process, a diffusion process, an etching process, a pre-cleaning process, a chamber cleaning process and a film forming process. The present embodiments will be described by way of an example in which the modification process such as the annealing process is performed. More specifically, the present embodiments will be described by way of an example in which a process of changing a composition or a crystal structure of a film formed on a surface of the wafer or a process of repairing a defect such as a crystal defect in the film is performed by heating the wafer by the annealing process.

### (1) Configuration of Substrate Processing Apparatus

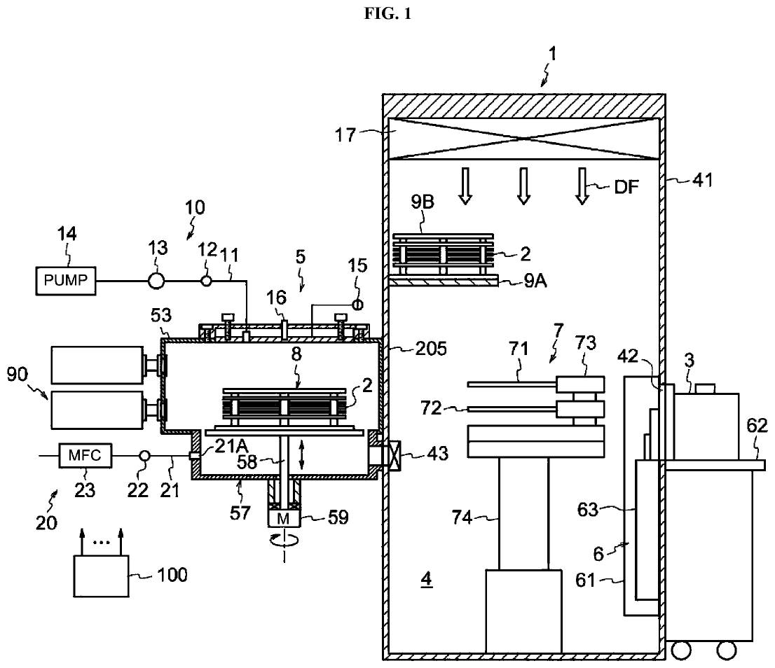

First, a configuration of a substrate processing apparatus 1 according to the present embodiments will be described mainly with reference to FIGS. 1 to 7. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

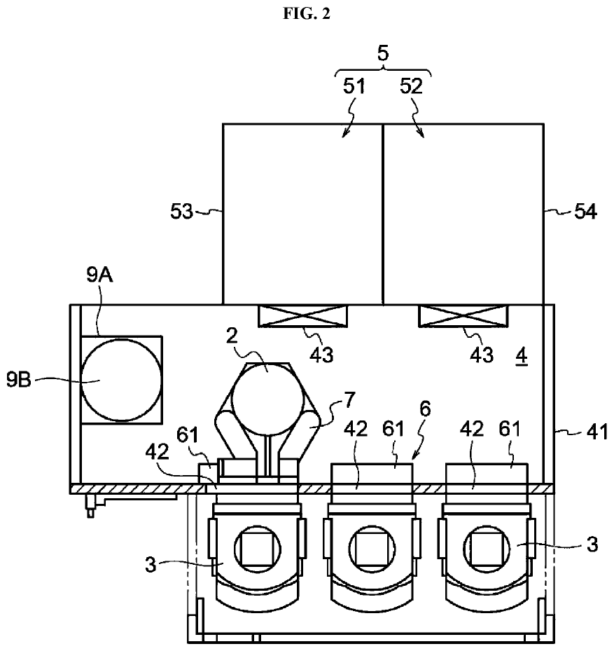

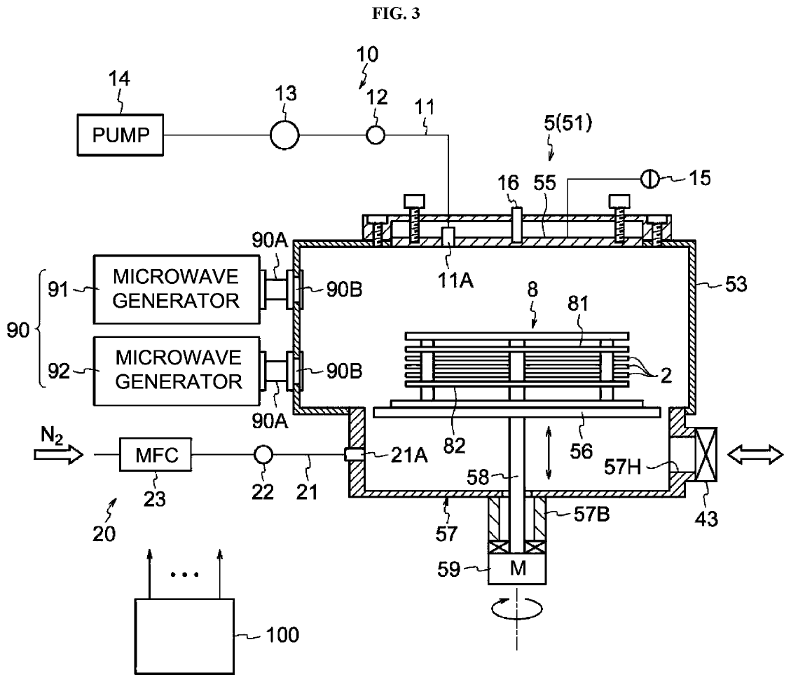

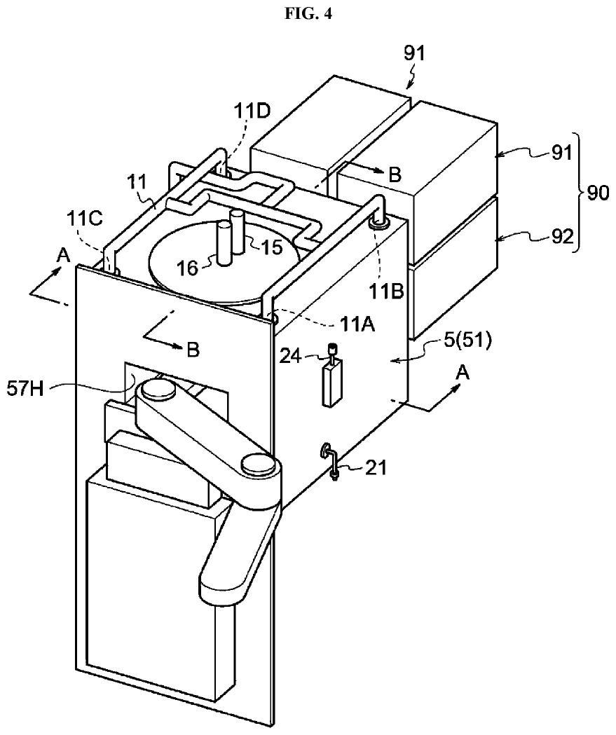

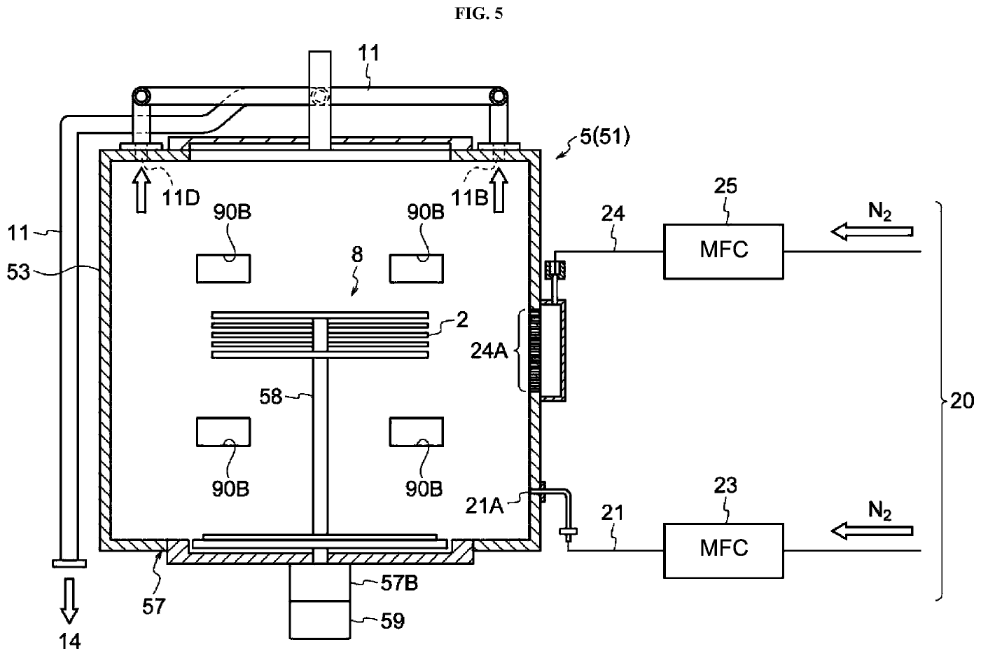

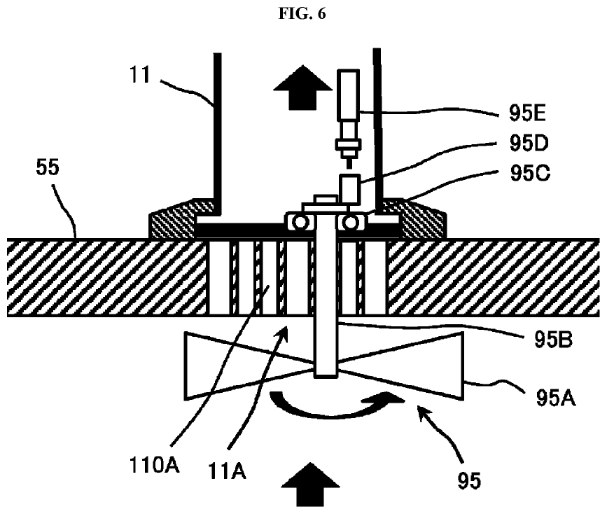

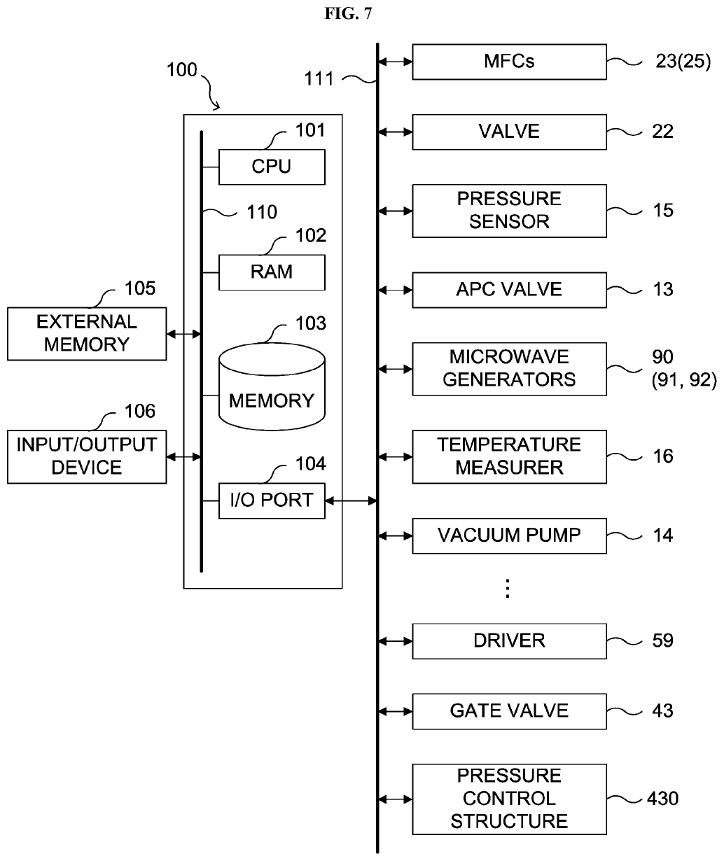

FIG. 1 is a diagram schematically illustrating a vertical cross-section of the substrate processing apparatus 1 according to the present embodiments, when viewed from side. FIG. 2 is a diagram schematically illustrating a horizontal cross-section of the substrate processing apparatus 1 shown in FIG. 1, when viewed from above. FIG. 3 is a diagram schematically illustrating an enlarged cross-section of a process chamber 5 of the substrate processing apparatus 1 shown in FIG. 1, when viewed from side. FIG. 4 is a diagram schematically illustrating a perspective view of the process chamber 5 shown in FIG. 3, when viewed from a transfer chamber 4 of the substrate processing apparatus 1 and when viewed from slightly above. FIG. 5 is a diagram schematically illustrating an enlarged cross-section (taken along a line A-A of FIG. 4) of the process chamber 5 shown in FIG. 3, when viewed from the transfer chamber 4. FIG. 6 is a diagram schematically illustrating a cross-section of a microwave stirrer 95 of the substrate processing apparatus 1 shown in FIG. 1, when viewed from side. FIG. 7 is a block diagram schematically illustrating a configuration of a controller 100 and related components of the substrate processing apparatus 1 shown in FIG. 1

### Overall Configuration of Substrate Processing Apparatus

In the substrate processing apparatus 1 according to the present embodiments, a pod (FOUP: Front Opening Unified Pod) 3 is used as a transfer container (also referred to as a “carrier”) when a wafer 2 to be processed (or a plurality of wafers including the wafer 2) is (or are) transferred. Hereinafter, the plurality of wafers including the wafer 2 may also be simply referred to as “wafers 2”.

Further, as shown in FIGS. 1 and 2, the substrate processing apparatus 1 may include: the transfer chamber (also referred to as a “transfer area”) 4 through which the wafer 2 is transferred; and the process chamber 5 in which the wafer 2 is processed. While the present embodiments will be described by way of an example in which the process chamber 5 is installed horizontally adjacent to the transfer chamber 4, the process chamber 5 may be installed vertically adjacent to the transfer chamber 4, specifically, adjacent to an upper portion or a lower portion of the transfer chamber 4.

### Transfer Chamber

The transfer chamber 4 is provided inside a transfer housing 41. For example, the transfer housing 41 is made of a metal material such as aluminum (Al) and stainless steel (SUS), or made of a material such as quartz.

A loading port structure (also referred as an “LP”) 6 is provided at a front side of the transfer housing 41 (that is, a right portion of FIG. 1). The loading port structure 6 serves as a pod opening/closing structure capable of opening and closing a lid (not shown) of the pod 3, and is configured such that the wafer 2 can be transferred (loaded) into the transfer chamber 4 from the pod 3 through a substrate loading/unloading port 42 provided at a front portion of the transfer housing 41 and transferred (unloaded) into the pod 3 from the transfer chamber 4 through the substrate loading/unloading port 42. The loading port structure 6 includes a housing 61, a stage 62 and an opener 63. The stage 62 is configured such that the pod 3 can be placed thereon and such that the pod 3 can be transferred to a position close to the substrate loading/unloading port 42 provided at the front portion of the transfer housing 41 of the transfer chamber 4. The opener 63 is configured to open and close the lid (not shown) provided at the pod 3. Further, the loading port structure 6 may be configured to be capable of purging an inside of the pod 3 with a purge gas. As the purge gas, an inert gas such as nitrogen (N₂) gas may be used. The transfer housing 41 may further include a purge gas circulation structure serving as a purge gas distribution structure. The purge gas circulation structure is configured to circulate the purge gas such as the nitrogen gas in the transfer chamber 4.

For example, gate valves 43 capable of opening and closing process chambers 51 and 52 are provided at a rear side of the transfer housing 41 (that is, a left portion of FIG. 1), respectively. Hereinafter, each of the gate valves 43 may also be to as a “gate valve 43”. In addition, a transfer device 7 serving as a substrate transfer structure (also referred to as a “substrate transfer robot”) capable of transferring the wafer 2 is provided in the transfer chamber 4. The transfer device 7 may include: tweezers (also referred to as “arms”) 71 and 72 serving as a placement structure on which the wafer 2 is placed; a transfer structure 73 capable of rotating or linearly moving each of the tweezers 71 and 72 in a horizontal direction; and a transfer structure elevator 74 capable of elevating and lowering the transfer structure 73. By consecutive operations of the tweezers 71 and 72, the transfer structure 73 and the transfer structure elevator 74, the transfer device 7 can load (charge) the wafer 2 into the pod 3 or a boat 8 (see FIGS. 1 and 3) serving as a substrate retainer disposed in the process chamber 5. Further, the transfer device 7 can unload (discharge) the wafer 2 from the pod 3 or the boat 8.

For example, a wafer support table (also referred to as a “wafer cooling table”) 9A is arranged in the transfer chamber 4, and a wafer support (also referred to as a “wafer cooling support” or a “wafer cooling boat”) 9B is provided on the wafer cooling table 9A. The wafer (which is heated) 2 is placed on the wafer cooling support 9B until it is sufficiently cooled. The wafer cooling support 9B is arranged in a space above the transfer chamber 4 and below a clean air supplier (which is a clean air supply structure) 17. A structure of the wafer cooling support 9B is similar to that of the boat 8, and includes a plurality of wafer supporting grooves from an upper portion to a lower portion of the wafer cooling support 9B. The wafer cooling support 9B is configured such that the wafers 2 are stacked (arranged) in a horizontal orientation in a multistage manner. As shown in FIG. 1, the wafer cooling support 9B and the wafer cooling table 9A are disposed in the transfer chamber 4 above installation positions of the substrate loading/unloading port 42 and the gate valve 43 and below the clean air supplier 17. That is, the wafer cooling support 9B and the wafer cooling table 9A are arranged outside a transfer path for transferring the wafer 2 from the pod 3 to the process chamber 5 using the transfer device 7. Therefore, it is possible to cool the wafer 2 after the wafer 2 is processed without reducing a throughput in a wafer processing (substrate processing) or a wafer transfer. In the present specification, when describing the present embodiments, the wafer cooling support 9B and the wafer cooling table 9A may be collectively referred to as a “cooling area” or a “cooling region”. Alternatively, the wafer cooling table 9A and the wafer cooling support 9B may be provided outside the transfer chamber 4. That is, for example, a cooling chamber may be provided between the process chambers 51 and 52, and the wafer cooling table 9A and the wafer cooling support 9B may be arranged in the cooling chamber.

### Process Chamber

The process chamber 5 functions as a process furnace of the substrate processing apparatus 1, and is constituted by the two process chambers 51 and 52. The process chamber 5 is provided on a side wall of the transfer housing 41 opposite to the pod 3. The process chambers 51 and 52 are arranged in cases 53 and 54 (which serve as process vessels), respectively. Hereinafter, unless they need to be distinguished separately, the process chambers 51 and 52 may be collectively or individually referred to as the “process chamber 5”. Further, a space surrounded by the cases 53 and 54 in which the process chamber 5 is disposed may also be described as a “process space”.

In the description of the process chamber 5 according to the present embodiments, since a configuration of the process chamber 51 is substantially the same as a configuration of the process chamber 52, the process chamber 51 will be described below, and the description of the process chamber 52 will be omitted.

As shown in FIG. 3, the process chamber 51 includes the case 53 serving as a cavity (process vessel) of a hollow rectangular parallelepiped shape. For example, the case 53 is made of a metal material such as aluminum (Al) capable of reflecting a microwave. In addition, a cap flange (which is a closing plate) 55 is provided on a ceiling (upper portion) of the case 53. Similar to the case 53, the cap flange 55 is made of a metal material or the like. The cap flange 55 is attached to the case 53 with a seal (not shown) interposed therebetween to airtightly seal an inside of the process chamber 5. The wafer 2 is processed inside the process chamber 5. As the seal described above, for example, an O-ring is used. In the present embodiments, in the process chamber 51, a reaction tube made of quartz and capable of transmitting the microwave may be installed in the case 53. In such a case, an inside of the reaction tube is effectively used as the process chamber 51. Alternatively, the case 53 may not be provided with the cap flange 55. In such a case, the case 53 with a closed ceiling may be used.

A loading/unloading structure 57 is provided at a bottom of the process chamber 51. A loading/unloading opening (also referred to as a “loading/unloading port”) 57H communicating with the transfer chamber 4 through the gate valve 43 is provided on a side wall of the loading/unloading structure 57 adjacent to the transfer chamber 4. A placement table (which is a mounting table) 56 capable of being moved vertically within the process chamber 51 is provided in the loading/unloading structure 57. The boat 8 is placed on an upper surface of the placement table 56. As the boat 8, for example, a quartz boat may be used. Susceptors 81 and 82 are arranged in the boat 8. The susceptors 81 and 82 are arranged so as to face each other and are spaced apart from each other in the vertical direction. The wafer 2 loaded into the loading/unloading structure 57 through the gate valve 43 and the loading/unloading port 57H is accommodated in the boat 8 while being interposed between the susceptor 81 and the susceptor 82.

The susceptors 81 and 82 are configured to indirectly heat the wafer 2 made of a dielectric material capable of self-heating (that is, generating heat) by absorbing the microwave. For example, a silicon semiconductor wafer (also referred to as a “Si wafer”) or a silicon carbide wafer (also referred to as a “SiC wafer”) may be used as the wafer 2. Therefore, the susceptors 81 and 82 may also be referred to as an “energy conversion structure”, a “radiant plate” or a “soaking plate”. In particular, the number of wafers to be accommodated (held) in the boat 8 is not limited. However, for example, the boat 8 is capable of holding three wafers including the wafer 2 stacked in the vertical direction with predetermined intervals therebetween. When the susceptors 81 and 82 are provided, it is possible to heat the wafer 2 (or the wafers 2) more uniformly and more efficiently by the radiant heat transferred from the susceptors 81 and 82. In addition, quartz plates serving as heat insulating plates may be disposed in the boat 8 above the susceptor 81 and below the susceptor 82, respectively.

The placement table 56 on which the boat 8 is placed is connected to and supported by an upper end of a shaft 58 serving as a rotating shaft at a center portion of a lower surface of the placement table 56. The other end (lower end) of the shaft 58 penetrates a bottom of the case 53 (that is, a bottom of the loading/unloading structure 57), and is connected to a driver (which is a driving structure) 59 arranged on the lower portion of the case 53. For example, an electric motor and an elevating apparatus are used as the driver 59. The other end of the shaft 58 is connected to a rotating shaft of the electric motor. Since the shaft 58 is connected to the driver 59, by rotating the shaft 58 by the driver 59, the placement table 56 and the wafer 2 accommodated in the boat 8 are rotated. According to the present embodiments, a bellows 57B capable of expanding and contracting in the vertical direction covers an outer circumference of the shaft 58 from the bottom of the loading/unloading structure 57 to the driver 59. The bellows 57B is configured to maintain the inside of the process chamber 5 and an inside of the transfer area 4 airtight.

The driver 59 is configured such that the placement table 56 can be elevated and lowered in the vertical direction between the bottom of the loading/unloading structure 57 and the bottom of the process chamber 5. That is, the driver 59 is configured to elevate the boat 8 from a position (which is a wafer loading/unloading position) at which the wafer 2 is accommodated in the loading/unloading structure 57 to a position (which is a wafer processing position) at which the wafer 2 is accommodated in the process chamber 5. On the contrary, the driver 59 is configured to lower the boat 8 from the position at which the wafer 2 is accommodated in the process chamber 5 to the position at which the wafer 2 is accommodated in the loading/unloading structure 57.

For example, in the process chamber 5, the loading/unloading port 57H is provided on a side surface (side wall) of the loading/unloading structure 57 adjacent to the transfer chamber 4. The loading/unloading port 57H is provided adjacent to the gate valve 43. The wafer 2 is loaded into the process chamber 5 from the transfer chamber 4 through the loading/unloading port 57H, and is unloaded to the transfer chamber 4 from the process chamber 5 through the loading/unloading port 57H. A choke structure (not shown) whose length is of 1/4 wavelength of the microwave used in the substrate processing is provided around the gate valve 43 or the loading/unloading port 57H. The choke structure is configured as a measure against a microwave leakage.

An electromagnetic wave supplier (which is an electromagnetic wave supply structure or an electromagnetic wave supply system) 90 serving as a heating apparatus is arranged on a side surface (side wall) of the case 53 opposite to the transfer chamber 4. According to the present embodiments, for example, the electromagnetic wave supplier 90 is constituted by a microwave generator 91 and a microwave generator 92. The microwave transmitted from the microwave generators 91 and 92 can be supplied into the process chamber 5 to heat the wafer 2 and to perform various processes on the wafer 2.

A temperature measurer (which is a temperature measuring structure) 16 is arranged on the cap flange 55 capable of sealing a ceiling of the process chamber 5. A non-contact type temperature sensor may be used as the temperature measurer 16. The temperature measurer 16 is configured to generate temperature information of an inner temperature of the process chamber 5 by measuring the inner temperature of the process chamber 5, and a flow rate of a cooling gas introduced through a gas supplier (which is a gas supply structure or a gas supply system) 20 to be described later can be adjusted based on the temperature information of the inner temperature of the process chamber 5. In addition, the temperature measurer 16 is configured to generate temperature information of the wafer 2 by measuring a temperature of the wafer 2, and parameters such as an output of the electromagnetic wave supplier 90 can be adjusted based on the temperature information of the wafer 2. As a result, a heating temperature of the wafer 2 can be adjusted. As the temperature sensor serving as the temperature measurer 16, for example, a radiation thermometer using infrared radiation (IR) may be practically used. A surface temperature of the wafer 2 is measured by the radiation thermometer. When the boat 8 is provided with the susceptor 81, a surface temperature of the susceptor 81 is measured by the radiation thermometer.

In the description of the present embodiments, the term “temperature of the wafer 2” or “wafer temperature” may refer to a wafer temperature converted by temperature conversion data (that is, an estimated wafer temperature), or may refer to a temperature obtained directly by measuring the temperature of the wafer 2 by the temperature measurer 16, or may refer to both of them. Further, the temperature conversion data may be obtained by acquiring a transition of a temperature change for each of the susceptor 81 and the wafer 2 and deriving a correlation between a temperature of the susceptor 81 and the temperature of the wafer 2 from the transition of the temperature change. For example, the temperature conversion data may be stored in advance in a memory 103 of the controller 100 described later or may be stored in an external memory 105 provided outside the controller 100. By preparing the temperature conversion data in advance in a manner described above, it is possible to estimate the temperature of the wafer 2 by measuring the temperature of the susceptor 81 alone.

The temperature measurer 16 is not limited to the radiation thermometer described above. For example, a thermometer using a thermocouple may be used as the temperature measurer 16 to measure the temperature of the wafer 2, or both the thermometer using the thermocouple and the non-contact type temperature sensor (non-contact type thermometer) may be used as the temperature measurer 16 to measure the temperature of the wafer 2. However, the thermometer using the thermocouple is used as the temperature measurer 16, and the thermocouple is disposed in the vicinity of the wafer 2 to measure the temperature of the wafer 2. Therefore, the thermocouple itself is heated by the microwave supplied from the electromagnetic wave supplier 90. As a result, it is difficult to accurately measure the temperature of the wafer 2. Therefore, it is practical to use the non-contact type thermometer as the temperature measurer 16. A location where the temperature measurer 16 is provided is not limited to the cap flange 55. For example, the temperature measurer 16 may be provided at the placement table 56. For example, instead of directly providing the temperature measurer 16 at the cap flange 55 or the placement table 56, the temperature measurer 16 may measure the temperature of the wafer 2 indirectly by measuring the radiation light reflected by a component such as a mirror and emitted through a measurement window (not shown) provided at the cap flange 55 or the placement table 56. While the present embodiments are described by way of an example in which one temperature measurer 16 is provided in the process chamber 5, the present embodiments are not limited thereto. For example, a plurality of temperature measurers including the temperature measurer 16 may be provided in the process chamber 5.

### Gas Supplier

In the substrate processing apparatus 1 according to the present embodiments, the gas supplier 20 through which a gas is supplied into the process chamber 5 is provided at a lower portion of the process chamber 5.

The gas supplier 20 includes a supply pipe 21 whose one end is connected to a supply port 21A arranged on a side wall of the loading/unloading structure 57 opposite to the loading/unloading port 57H of the loading/unloading structure 57. The supply port 21A is arranged below an exhaust port 11A of an exhaust pipe 11. The other end of the supply pipe 21 is connected to a gas supply source (not shown) through a valve 22 and a mass flow controller (MFC) 23 interposed therebetween in series. For example, the valve 22 is used as an opening/closing valve. The MFC 23 functions as a flow rate controller. The gas supply source is configured to supply a process gas used for the substrate processing. A gas such as an inert gas, a source gas and a reactive gas may be used as the process gas. The process gas supplied from the gas supply source is supplied into the process chamber 5. According to the present embodiments, as the inert gas, specifically, nitrogen (N₂) gas is supplied from the gas supply source into the process chamber 5.

For example, as shown in FIGS. 4 and 5, the gas supplier 20 includes a supply pipe 24 whose one end is connected to a supply port 24A arranged at an intermediate portion of the case 53 in the vertical direction. The supply port 24A is arranged below the exhaust port 11A of the exhaust pipe 11 and above the supply port 21A of the supply pipe 21. The other end of the supply pipe 24 is connected to a gas supply source (not shown) through a valve (not shown) whose configuration is substantially the same as that of the valve 22 and a mass flow controller (MFC) 25 interposed therebetween in series. The gas supply source connected to the other end of the supply pipe 24 is the same as the gas supply source connected to the other end of the supply pipe 21. In the present embodiments, an intermediate gas supplier (which is an intermediate gas supply structure or an intermediate gas supply system) is constituted by the supply pipe 24 and the MFC 25 (that is, a part of the gas supplier 20). For example, the supply port 24A is constituted by an assembly of a plurality of through-holes provided in a rectangular area of the side wall of the case 53. In other words, the supply port 24A is formed in a mesh shape. For example, the N₂ gas supplied into the process chamber 5 through the supply port 24A is uniformly dispersed within the process chamber 5. Thereby, it is possible to uniformly perform the process (substrate processing) on a surface of the wafer 2 or on surfaces of the wafers 2 accommodated in the boat 8.

When two or more kinds of gases are supplied into the process chamber 5 during the substrate processing, it is possible to supply the two or more kinds of gases by connecting a supply pipe (or a plurality of gas supply pipes) to the supply pipe 21 between the process chamber 5 and the valve 22 shown in FIG. 3. The supply pipe (or the plurality of the gas supply pipes) may be connected to a gas supply source (or a plurality of gas supply sources: not shown) configured to supply the two or more kinds of gases through a valve (or valves) and an MFC (or MFCs) interposed therebetween in series from a downstream side (or downstream sides) to an upstream side (or upstream sides) of the supply pipe (or the plurality of the gas supply pipes). Further, supply pipes installed in parallel may be provided to be directly connected to the process chamber 5 from a gas supply source that supplies a plurality of types of gases, and a valve and an MFC may be disposed in each supply pipe.

According to the present embodiments, the gas supplier 20 is constituted by the supply pipe 21, the valve 22 and the MFC 23. The gas supplier 20 may further include the gas supply source (not shown). Further, the gas supplier 20 may further include the supply pipe 24 shown in FIG. 5, the valve (not shown) and the MFC 25, which serve as the intermediate gas supplier, and may further include the gas supply source connected to the supply pipe 24. For example, as the inert gas supplied by the gas supplier 20, in addition to or instead of the N₂ gas, a rare gas such as argon (Ar) gas, helium (He) gas, neon (Ne) gas and xenon (Xe) gas may be used.

### Gas Exhauster

As shown in FIGS. 1 and 3, an exhauster (which is an exhaust structure or an exhaust system) 10 is provided at an upper portion of the process chamber 5 in the substrate processing apparatus 1 according to the present embodiments. The exhauster 10 is configured to exhaust an inner atmosphere of the process chamber 5. The exhauster 10 serves as a gas exhauster (which is a gas exhaust structure or a gas exhaust system) through which the gas is exhausted from the process chamber 5.

In order to perform such an exhaust described above, as shown in a simplified manner in FIG. 3, the exhauster 10 is provided with the exhaust port 11A in the ceiling of the process chamber 5, and one end of the exhaust pipe 11 is connected to the exhaust port 11A. More specifically, according to the present embodiments, a total of four exhaust ports 11A, 11B, 11C and 11D are arranged at four locations corresponding to four corners of the ceiling of the process chamber 5, as shown in FIGS. 4 and 5. In the present embodiments, each of the exhaust ports 11A, 11B, 11C and 11D may also be simply referred to as the “gas exhauster”. That is, four gas exhausters may be provided. Referring to FIG. 4, when viewed from the transfer chamber 4 toward the process chamber 5, the exhaust port 11A is arranged at a front right corner of the ceiling of the process chamber 5, and the exhaust port 11B is arranged at a back right corner of the ceiling of the process chamber 5. Further, the exhaust port 11C is arranged at a front left corner of the ceiling of the process chamber 5, and the exhaust port 11D is arranged at a back left corner of the ceiling of the process chamber 5. By arranging the exhaust ports 11A to 11D particularly at the four corners of the ceiling, it is possible to reduce a “heat build-up” in an upper space inside the process chamber 5. Thereby, it is possible to improve an exhaust efficiency even when the number of the exhaust ports is small. In addition, although it is sufficient that the exhaust port is disposed at at least one location, it is possible to further improve the exhaust efficiency by disposing the exhaust ports at two or more locations.

Each of the exhaust ports 11A to 11D is constituted by an assembly of a plurality of through-holes (exhaust holes) provided in an area of each of the exhaust ports 11A to 11D. In other words, each of the exhaust ports 11A to 11D is constituted by a plurality of exhaust holes. Further, each of the exhaust ports 11A to 11D is configured such that the inner atmosphere of the process chamber 5 (that is, the gas in the process chamber 5) can be exhausted through the plurality of exhaust holes of each of the exhaust ports 11A to 11D.

One ends of divided portions of the exhaust pipe 11 are connected to the exhaust ports 11A to 11D, respectively. The other ends of the divided portions of the exhaust pipe 11 are joined together to form the exhaust pipe 11. As conceptually shown in FIG. 3, the exhaust pipe 11 is connected to a vacuum pump 14 with a valve 12 and a pressure regulator (which is a pressure adjusting structure) 13 interposed therebetween in series. The valve 12 is used as an opening/closing valve. As the pressure regulator 13, for example, a pressure controller valve such as an APC (adaptive pressure control) valve configured to control a valve opening degree according to an inner pressure of the process chamber 5 may be used. However, the pressure regulator 13 is not limited to the pressure controller valve as long as it can adjust an exhaust amount of the gas based on pressure information on the inner pressure of the process chamber 5. For example, the pressure regulator 13 may be implemented by using both of a normal opening/closing valve or a pressure regulating valve (pressure controller valve). The pressure information may be obtained from a pressure sensor 15 disposed on a top plate (ceiling) of the process chamber 5.

According to the present embodiments, the exhauster 10 is constituted by the exhaust ports 11A to 11D, the exhaust pipe 11, the valve 12 and the pressure regulator 13. The exhauster 10 may further include the vacuum pump 14. In the present embodiments, the exhauster 10 conceptually shown in FIG. 3 is disposed above the process chamber 5. However, in reality, as shown in FIG. 4, the divided portions of the exhaust pipe 11 are joined together above the process chamber 5 and are piped downward along an outer wall of the case 53. The valve 12 and the pressure regulator 13 are disposed in the middle of the exhaust pipe 11 piped downward, and the exhaust pipe 11 is connected to the vacuum pump 14. In the description of the present embodiments, the exhauster 10 may be described simply as the “exhaust system” or simply as an “exhaust line”.

### Microwave Supplier

The substrate processing apparatus 1 according to the present embodiments includes the electromagnetic wave supplier 90 serving as a microwave supplier (which is a microwave supply structure or a microwave supply system) configured to supply the microwave into the process chamber 5.

Specifically, as shown in FIGS. 3 and 5, a plurality of electromagnetic wave introduction ports 90B that penetrate from inside to outside of the process chamber 5 are provided on the side wall of the case 53 of the process chamber 5 opposite to the transfer chamber 4. According to the present embodiments, as shown in FIG. 5, for example, two electromagnetic wave introduction ports 90B are arranged in the vertical direction and two electromagnetic wave introduction ports 90B are arranged in the horizontal direction. That is, a total of four electromagnetic wave introduction ports 90B are arranged. Each of the electromagnetic wave introduction ports 90B is of a rectangular shape whose longitudinal direction is a left-right direction when viewed from the transfer chamber 4 toward the process chamber 5. The number and the shape of the electromagnetic wave introduction ports 90B are not particularly limited. One end of each of waveguides 90A is connected to each of the electromagnetic wave introduction ports 90B, and the other end of each of the waveguides 90A is connected to the electromagnetic wave supplier 90. According to the present embodiments, the microwave generators 91 and 92 are used as the electromagnetic wave supplier 90. The microwave generator 91 is connected to the electromagnetic wave introduction ports 90B arranged on the upper portion of the process chamber 5 through an upper one of the waveguides 90A. The microwave generated and transmitted by the microwave generator 91 is supplied into the process chamber 5 through the upper one of the waveguides 90A and the electromagnetic wave introduction ports 90B arranged on the upper portion of the process chamber 5. The microwave generator 92 is connected to the electromagnetic wave introduction ports 90B arranged on the lower portion of the process chamber 5 through a lower one of the waveguides 90A. The microwave generated and transmitted by the microwave generator 92 is supplied into the process chamber 5 through the lower one of the waveguides 90A and the electromagnetic wave introduction ports 90B arranged on the lower portion of the process chamber 5.

For example, a magnetron or a klystron may be used as each of the microwave generators 91 and 92. Preferably, a frequency of the microwave generated by each of the microwave generators 91 and 92 is controlled such that the frequency is equal to or higher than 13.56 MHz and equal to or lower than 24.125 GHz. More preferably, the frequency is controlled to a frequency of 2.45 GHz or less or a frequency of 5.8 GHz or less. The frequency of the microwave generated by the microwave generator 91 is equal to the frequency of the microwave generated by the microwave generator 92. Alternatively, the frequency of the microwave generated by the microwave generator 91 may be different from the frequency of the microwave generated by the microwave generator 92. In addition, the electromagnetic wave supplier 90 may include one microwave generator for the process chamber 5, or may include two, three or equal to or more than five microwave generators for the process chamber 5. For example, the microwave generators 91 and 92 may be arranged on a side wall of the case 53 of the process chamber 5 other than the side wall exemplified above.

The microwave generators 91 and 92 are connected to the controller 100 described later in detail, and operations of the microwave generators 91 and 92 are controlled by the controller 100. More specifically, the microwave generators 91 and 92 are controlled by the same control signal transmitted from the controller 100. Alternatively, the microwave generator 91 and the microwave generator 92 may be individually controlled by individual control signals transmitted from the controller 100 to the microwave generator 91 and the microwave generator 92, respectively.

### Microwave Stirrer

In addition to the electromagnetic wave supplier 90 described above, the substrate processing apparatus 1 according to the present embodiments further includes the microwave stirrer (which is a microwave stirring structure or a microwave stirring system) 95 configured to stir the microwave (which is supplied by the electromagnetic wave supplier 90) inside the process chamber 5.

The microwave stirrer 95 is configured to stir the microwave by being rotated due to a flow of the gas in the process chamber 5. The microwave stirrer 95 is provided corresponding to at least one of the exhaust ports 11A to 11D. In other words, a single microwave stirrer 95 may be provided corresponding to one of the exhaust ports 11A to 11D, or a plurality of microwave stirrers including the microwave stirrer 95 may be provided selectively corresponding to some of the exhaust ports 11A to 11D or individually provided corresponding to an entirety of the exhaust ports 11A to 11D. Further, the microwave stirrer 95 is preferably provided at a location where the microwave stirrer 95 can be rotated due to the flow of the gas in the process chamber 5. For example, the microwave stirrer 95 may be provided on a side surface (side wall) between the supply port 24A and the exhaust port 11A such that the microwave stirrer 95 is configured to be rotated by the gas supplied through the supply port 24A. The present embodiments will be described by way of an example in which the single microwave stirrer 95 is provided corresponding to the exhaust port 11A.

In order to stir the microwave, as shown in FIG. 6, the microwave stirrer 95 is provided with a stirrer fan (which is a blade) 95A. For example, the stirrer fan 95A is of a propeller shape and is made of a high dielectric material whose dielectric loss is low, such as a metal material or a ceramic material. For example, when the stirrer fan 95A is made of the metal material such as aluminum, it is possible to reduce a surface irregularity by polishing a surface of the stirrer fan 95A. Thereby, it is possible to increase a reflection efficiency of microwave. As a result, it is possible to easily stir the microwave. For example, when the stirrer fan 95A is of the propeller shape, the stirrer fan 95A is configured to be capable of being rotated in accordance with the flow of the gas. Further, when the stirrer fan 95A is rotated, it is possible to stir the microwave so as to prevent a standing wave of the microwave from being generated in the process chamber 5.

The stirrer fan 95A is rotatably supported by a rotating shaft 95B. The rotating shaft 95B penetrates through one of a plurality of exhaust holes 110A included in the exhaust port 11A, and is supported by a support structure 95C constituted by components such as a bearing and a support thereof at a penetration location (that is, a portion of the cap flange 55 provided with the exhaust port 11A located opposite to the stirrer fan 95A). That is, the rotating shaft 95B supporting the stirrer fan 95A is attached to one of the plurality of exhaust holes 110A in the exhaust port 11A.

A flag 95D capable of being detected by a detection sensor 95E may be attached to the rotating shaft 95B. By detecting the flag 95D by using the detection sensor 95E, it is possible to detect whether or not the stirrer fan 95A and the rotating shaft 95B are rotated. For example, when the detection sensor 95E detects that the stirrer fan 95A and the rotating shaft 95B are not being rotated based on the flag 95D while the microwave is being supplied into the process chamber 5, the controller 100 described later may control the MFC 23 of the gas supplier 20 to increase a supply flow rate of the inert gas such that the stirrer fan 95A and the rotating shaft 95B are rotated.

According to the microwave stirrer 95 configured as described above, since the microwave stirrer 95 is rotated using the flow of the gas in the process chamber 5 and thereby stirs the microwave, it is possible to stir the microwave without separately preparing a drive source (for example, an electric motor) for stirring the microwave. Further, since the microwave stirrer 95 is installed using one of the plurality of exhaust holes 110A included in the exhaust port 11A of a multi-hole structure, it is possible to stir the microwave without making major structural changes to the exhaust port 11A, and it is also possible to prevent (or suppress) an airtightness within the process chamber 5 including the exhaust pipe 11 from being damaged. Furthermore, since the microwave stirrer 95 is provided corresponding to the exhaust port 11A, it is possible to prevent (or suppress) particles and the like from diffusing into the process chamber 5.

### Controller

As shown in FIGS. 1 and 3, the substrate processing apparatus 1 according to the present embodiments includes the controller (which is a control structure) 100 configured to control an overall operation of the substrate processing apparatus 1.

As shown in FIG. 7, the controller 100 is constituted by a central processing unit (CPU) 101, a random access memory (RAM) 102, the memory 103 and an input/output (I/O) port 104. That is, the controller 100 is configured as a computer. In the description of the present embodiments, the central processing unit 101 is simply referred to as the CPU 101, the random access memory 102 is simply referred to as the RAM 102, and the input/output port 104 is simply referred to as the I/O port 104.

The CPU 101 is connected to each of the RAM 102, the memory 103 and the I/O port 104 through an internal bus 110, and is configured to exchange (that is, transmit or receive) various information with each of the RAM 102, the memory 103 and the I/O port 104. An input/output device 106 is connected to the controller 100 through the internal bus 110. As the input/output device 106, a component such as a touch panel, a keyboard and a mouse may be used. As the memory 103, for example, a component such as a flash memory, a hard disk drive (HDD) and a solid state drive (SSD) may be used.

For example, a control program for controlling a substrate processing operation of the substrate processing apparatus 1 and a process recipe may be readably stored in the memory 103. The process recipe contains information on sequences and conditions of the annealing process (modification process), and is obtained by combining steps of the substrate processing such that the controller 100 can execute the steps to acquire a predetermined result, and functions as a program (software). In the description of the present embodiments, the control program and the process recipe may be collectively or individually referred to as a “program”. Further, the process recipe may be simply referred to as a “recipe”. Thus, in the present specification, the term “program” may refer to the recipe alone, may refer to the control program alone, or may refer to both of the recipe and the control program. The RAM 102 functions as a memory area (work area) where a program or data read by the CPU 101 is temporarily stored.

The I/O port 104 is connected to the components described above such as the MFC 23, the valve 22, the pressure sensor 15, the pressure regulator 13, the electromagnetic wave supplier 90, the temperature measurer 16, the vacuum pump 14, the gate valve 43, the driver 59 and a pressure control structure 430. An external bus 111 is used to connect the I/O port 104 to the components described above.

In the controller 100 with such a configuration described above, the CPU 101 is configured to read the control program from the memory 103 and execute the read control program. Furthermore, the CPU 101 is configured to read the recipe from the memory 103 in accordance with an operation command inputted from the input/output device 106. In accordance with the contents of the read recipe, the CPU 101 is configured to be capable of controlling operations such as a flow rate adjusting operation for various gases by using the MFC 23, an opening/closing operation of the valve 22, a pressure adjusting operation by using the pressure regulator 13 based on the pressure sensor 15, a start and stop of the vacuum pump 14. The CPU 101 is further configured to be capable of controlling operations such as a rotating operation, a rotation speed adjusting operation and an elevating and lowering operation of the placement table 56 (or the boat 8) by the driver 59. The CPU 101 is further configured to be capable of controlling operations such as an output adjusting operation by the electromagnetic wave supplier 90 based on the temperature measurer 16. More specifically, when the temperature of the wafer 2 (that is, the inner temperature of the process chamber 5) is measured by using the temperature measurer 16, the inner temperature measured by using the temperature measurer 16 is transmitted to the controller 100 as the temperature information. In such a case, the CPU 101 is configured to be capable of adjusting (controlling) outputs of the microwave generators 91 and 92 based on the temperature information so as to adjust the heating temperature of the wafer 2 (that is, a process temperature of the wafer 2). As a method of adjusting the outputs of the microwave generators 91 and 92, for example, a voltage input level of each of the microwave generators 91 and 92 may be adjusted or a voltage input duration (that is, a ratio of a power ON time and a power OFF time) of each of the microwave generators 91 and 92 may be adjusted. Further, the CPU 101 is configured to be capable of adjusting a supply flow rate of the gas by the MFC 23 based on the detection sensor 95E.

For example, the program stored in the external memory 105 is installed in the controller 100. As the external memory 105, for example, a magnetic disk such as a hard disk, a magneto-optic (MO) disk or an optical disk such as a compact disk (CD) may be used. In addition, as the external memory 105, a semiconductor memory such as a universal serial bus (USB) memory may be used. In the present specification, the memory 103 and the external memory 105 may be embodied by a non-transitory computer readable recording medium (or a non-transitory computer readable-and-writable recording medium) in which the program and the data are stored readable or writable. Hereafter, the memory 103 and the external memory 105 may be collectively or individually referred to as a “recording medium”. Thus, in the description of the present embodiments, the term “recording medium” may refer to the memory 103 alone, may refer to the external memory 105 alone or may refer to both of the memory 103 or the external memory 105. Instead of using the memory 103 or the external memory 105, a communication interface such as the Internet and a dedicated line may be used to provide the program to the controller 100.

### (2) Substrate Processing

Subsequently, the substrate processing of processing the wafer 2 by using the substrate processing apparatus 1 described above, which is a part of the manufacturing process of the semiconductor device, will be described. In the following descriptions, operations of the components constituting the substrate processing apparatus 1 are controlled by the controller 100.

The present embodiments will be described by way of an example in which a processing of modifying (crystallizing) an amorphous silicon film formed on the wafer (substrate) 2 is performed as the substrate processing. Since in the present embodiment a plurality of the process chambers 51 and 52 are provided for the substrate processing apparatus 1 and the same processing is performed in each of the process chambers 51 and 52 based on the same recipe, the processing using the process chamber 51 will be described, and the processing using the process chamber 52 will be omitted.

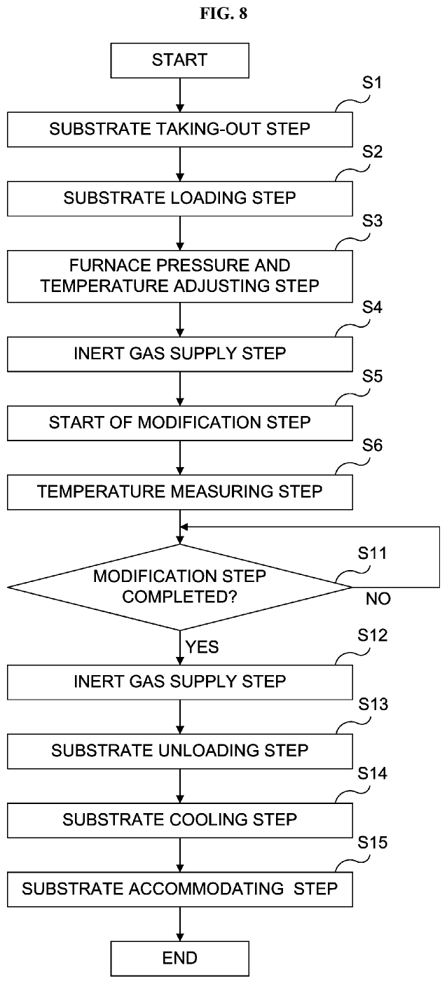

FIG. 8 is a flow chart schematically illustrating the substrate processing according to the present embodiments.

### Substrate Taking-Out Step (Step S1)

When the substrate processing shown in FIG. 8 is performed, first, in a substrate taking-out step S1, the transfer device 7 in the transfer chamber 4 of the substrate processing apparatus 1 takes out a predetermined number of wafers including the wafer 2 to be processed from the pod 3 opened by the loading port structure 6. Then, the predetermined number of the wafers including the wafer 2 are placed on one or both of the tweezers 71 and 72.

### Substrate Loading Step (Step S2)

Subsequently, in a substrate loading step S2, the wafer 2 placed on one of the tweezers 71 and 72 (or the predetermined number of wafers including the wafer 2 placed on both of the tweezers 71 and 72) is (or are) transferred (loaded) into the process chamber 5 while the loading/unloading port 57H is opened by the opening/closing operation of the gate valve 43. That is, the boat 8 is loaded into the process chamber 5. In the present step, the boat 8 is lowered to the loading/unloading structure 57 of the process chamber 5, and the wafer 2 is accommodated in the boat 8. By elevating the placement table 56 by the driver 59, the boat 8 (that is, the wafer 2 accommodated in the boat 8) is loaded into the process chamber 5.

### Furnace Pressure and Temperature Adjusting Step (Step S3)

Thereafter, in a furnace pressure and temperature adjusting step S3, the inner pressure of the process chamber 5 (also referred to as an “inner pressure of a furnace”) is adjusted to a predetermined pressure. For example, the inner pressure of the process chamber 5 is adjusted to a pressure within a range from 10 Pa to 102,000 Pa. Specifically, the valve opening degree of the pressure regulator 13 is feedback-controlled based on the pressure information detected by the pressure sensor 15 to adjust the inner pressure of the process chamber 5 to the predetermined pressure while the vacuum pump 14 exhausts the inner atmosphere of the process chamber 5. In addition, in parallel with adjusting the inner pressure of the process chamber 5, the electromagnetic wave supplier 90 is controlled as a preliminary heating such that the inside of the process chamber 5 is heated to a predetermined temperature by transmitting the microwave from the microwave generators 91 and 92. When the inner temperature of the process chamber 5 is elevated to a predetermined substrate processing temperature by the electromagnetic wave supplier 90, in order to prevent the wafer 2 from being deformed or damaged, it is preferable to elevate the inner temperature of the process chamber 5 while the output of the electromagnetic wave supplier 90 is controlled to be less than that of the electromagnetic wave supplier 90 in a modification step S5. In addition, when the substrate processing is performed under the atmospheric pressure, an inert gas supply step (step S4) described below may be performed after adjusting the inner temperature of the process chamber 5 alone without adjusting the inner pressure of the process chamber 5.

### Inert Gas Supply Step (Step S4)

After the inner pressure and the inner temperature of the process chamber 5 are respectively adjusted to predetermined values by performing the step S3, in the inert gas supply step S4, the driver 59 rotates the shaft 58 to rotate the wafer 2 accommodated in the boat 8 on the placement table 56. While the driver 59 rotates the wafer 2, a supply of the inert gas serving as the cooling gas into the process chamber 5 is started through the gas supplier 20. For example, the N₂ gas is used as the inert gas. For example, the N₂ gas is supplied from the gas supply source (not shown) into the loading/unloading structure 57 at the lower portion of the process chamber 5 through the supply port 21A of the supply pipe 21 via the MFC 23 and the valve 22 interposed therebetween. In addition, along with the supply of the inert gas, the operation of the exhauster 10 is started to exhaust the inner atmosphere of the process chamber 5. Specifically, the operation of the vacuum pump 14 of the exhauster 10 is started, and the inner atmosphere of the process chamber 5 is exhausted by the vacuum pump 14 through the exhaust ports 11A, 11B, 11C and 11D of the exhaust pipe 11 via the valve 12 and the pressure regulator 13 interposed therebetween. For example, the inner pressure of the process chamber 5 is adjusted to 10 Pa or more and 102,000 Pa or less, preferably 101,300 Pa or more and 102,000 Pa or less. For example, the inert gas supply step S4 may be started when a supply of the microwave is started from the electromagnetic wave supplier 90 in the modification step S5 described later.

### Modification Step (Step S5)

When the inner pressure of the process chamber 5 is maintained at a predetermined pressure by the inert gas supply step S4, the modification step S5 is then started. When the modification step S5 is started, the microwave is supplied into the process chamber 5 from the electromagnetic wave supplier 90. By supplying the microwave into the process chamber 5, the wafer 2 is heated to a temperature of 100° C. or more and 1,000° C. or less, preferably 400° C. or more and 900° C. or less. It is more preferable that the wafer 2 is heated to a temperature of 500° C. or more and 700° C. or less. By performing the substrate processing at the temperature described above, it is possible for the wafer 2 to efficiently absorb the microwave. Thereby, it is possible to improve a process speed of the modification process of the substrate processing. In other words, when the wafer 2 is processed at a temperature lower than 100° C. or higher than 1,000° C., the surface of the wafer 2 is deformed, so that the microwave is hardly absorbed on the surface of the wafer 2. Thus, it may be difficult to efficiently heat the wafer 2.

In the present step, when the supply of the microwave into the process chamber 5 is started, the nitrogen gas serving as the cooling gas is supplied into the process chamber 5 from the intermediate gas supplier simultaneously with the supply of the microwave. That is, the nitrogen gas is supplied from the gas supply source into the process chamber 5 through the supply port 24A of the supply pipe 24 via the MFC 25 and the valve (not shown) interposed therebetween. When the supply of the microwave is started, the inner temperature of the process chamber 5 is elevated rapidly. In addition to supplying the cooling gas from the gas supplier 20 into the process chamber 5, the cooling gas is supplied from the intermediate gas supplier into the process chamber 5. As a result, it is possible to effectively suppress or prevent the heat build-up in the upper portion of the process chamber 5.

When a microwave heating is performed in a manner described above, the standing wave may be generated in the process chamber 5. Thereby, a “heat concentrated region” (also referred to as a “hot spot”) which is locally heated and an “unheated region” which is not heated may be formed on the wafer 2. In other words, in a case where the microwave heating is performed (that is, the wafer 2 is heated by the microwave), a uniformity of a temperature distribution on the wafer 2 may deteriorate. When the uniformity of the temperature distribution deteriorates, the modification process on the wafer 2 may not be properly performed, or the wafer 2 may be deformed. Thereby, a productivity of the substrate processing may deteriorate. Thus, it is preferable to prevent the uniformity of the temperature distribution from deteriorating.

Therefore, according to present embodiments, the microwave stirrer 95 is provided in the process chamber 5. Then, the stirrer fan 95A is rotated in accordance with the flow of the gas exhausted through exhaust port 11A. Thereby, the microwave supplied by the electromagnetic wave supplier 90 can be stirred. By stirring the microwave, it is possible to prevent the standing wave of the microwave from being generated in the process chamber 5.

That is, according to present embodiments, the microwave stirrer 95 stirs the microwave supplied from the electromagnetic wave supplier 90 by rotating the stirrer fan 95A. Thereby, it is possible to prevent the standing wave of the microwave from being generated in the process chamber 5. Therefore, even when the microwave heating is performed, it is possible to prevent (or suppress) the uniformity of the temperature distribution on the wafer 2 from deteriorating. As a result, it is possible to improve a uniformity of the substrate processing on the surface of the wafer 2.

In addition, according to present embodiments, the stirrer fan 95A is rotated to stir the microwave by the flow of the gas in the process chamber 5, specifically, by the flow of the gas exhausted through the exhaust port 11A. In other words, in the modification step S5, the flow of the gas constantly occurs in the process chamber 5. Thus, by utilizing the flow of the gas (which constantly occurs) to rotate the stirrer fan 95A, it is possible to reliably stir the microwave, and it is possible to stir the microwave without separately preparing the drive source (for example, the electric motor) for stirring the microwave. Further, by particularly utilizing the flow of gas exhausted through the exhaust port 11A, it is possible to prevent (or suppress) the particles and the like from diffusing into the process chamber 5.

### Temperature Measuring Step (Step S6)

While performing the modification step S5 described above, the inner temperature of the process chamber 5 is measured using the temperature measurer 16. In the present step, the non-contact type temperature sensor is used as the temperature measurer 16, and the process temperature is controlled based on the temperature information measured by the temperature measurer 16. Specifically, the inner temperature of the process chamber 5 is adjusted by controlling a turn-on/turn-off of the power of the electromagnetic wave supplier 90 based on the temperature information measured by the temperature measurer 16. Further, an upper limit threshold and a lower limit threshold of the inner temperature of the process chamber 5 is stored in the memory 103 in advance. Based on the temperature information obtained from the temperature measurer 16, it is possible to adjust the flow rate of the cooling gas supplied into the process chamber 5 through the gas supplier 20.

By performing the modification step S5 while performing a temperature control in a manner described above, the wafer 2 is heated, and the amorphous silicon film formed on the surface of the wafer 2 is modified (or crystallized) into a polysilicon film. That is, it is possible to form the polysilicon film (which is uniformly crystallized) on the wafer 2.

### Determination Step (Step S11)

Thereafter, the controller 100 determines whether the modification step S5 is completed (step S11). Specifically, the controller 100 determines whether or not a predetermined time (that is, a pre-set process time) has elapsed. When it is determined that the predetermined time has not elapsed, that is, it is determined that the modification step S5 is not completed, the modification step S5 is continuously performed. On the other hand, when it is determined that the predetermined time has elapsed, a rotation of the boat 8, the supply of the inert gas (cooling gas), the supply of the microwave and an exhaust of the inside of the process chamber 5 are stopped, and the modification step S5 is terminated.

### Inert Gas Supply Step (Step S12)

When it is determined that the modification step S5 is completed, the inner pressure of the process chamber 5 is adjusted to be lower than an inner pressure of the transfer chamber 4 by adjusting at least one of the pressure regulator 13 or the pressure control structure 430 of the transfer chamber 4. Then, the gate valve 43 is opened. Thereby, the purge gas circulating inside the transfer chamber 4 is exhausted from the lower portion toward the upper portion of the process chamber 5. As a result, it is possible to effectively suppress the heat build-up in the upper portion of the process chamber 5.

### Substrate Unloading Step (Step S13)

By opening the gate valve 43, the process chamber 5 is in communication with the transfer chamber 4. Then, the wafer 2 accommodated in the boat 8 after the modification step is transferred from the process chamber 5 into the transfer chamber 4 by the tweezers 71 and 72 of the transfer device 7.

### Substrate Cooling Step (Step S14)

The wafer 2 unloaded by the tweezers 71 and 72 is moved to the cooling area by consecutive operations of the transfer structure 73 and the transfer structure elevator 74. Then, the wafer 2 is placed on the wafer cooling support 9B by the tweezers 71. According to the present embodiments, by locating the cooling area in the vicinity of the clean air supplier 17, that is, at a position facing at least a portion of a purge gas outlet port of the clean air supplier 17, it is possible to improve a cooling efficiency for the wafer 2. Further, since the purge gas containing few particles is used to cool the wafer 2, it is possible to improve a quality of the surface of the wafer 2 or a quality of the film formed on the surface of the wafer 2.

### Substrate Accommodating Step (Step S15)

Then, the wafer 2 cooled in the cooling area is accommodated in the pod 3 of loading port structure 6 by the transfer device 7.

By repeatedly performing the operations described above, the modification process is performed on the wafer 2. Thereby, the substrate processing according to the present embodiments is completed.

(3) Effects according to Present Embodiments

According to the present embodiments, it is possible to obtain one or more effects described below.
(a) According to the present embodiments, the microwave stirrer 95 is rotated to stir the microwave supplied from the electromagnetic wave supplier 90. Thereby, it is possible to prevent the standing wave of the microwave from being generated in the process chamber 5. Therefore, even when the microwave heating is performed, it is possible to prevent (or suppress) the uniformity of the temperature distribution on the wafer 2 from deteriorating, and it is also possible to improve the uniformity of the substrate processing on the surface of the wafer 2. Thereby, it is possible to properly perform the substrate processing on the wafer 2, and it is possible to prevent (or suppress) the wafer 2 from being deformed. As a result, it is possible to prevent (or suppress) the productivity of the substrate processing from deteriorating. In other words, according to the present embodiments, when the microwave heating is performed, it is possible to prevent (or suppress) the uniformity of the temperature distribution on the wafer 2 from deteriorating, and thereby, it is possible to prevent (or suppress) the productivity of the substrate processing on the wafer 2 from deteriorating.

Furthermore, according to the present embodiments, the microwave stirrer 95 is configured to stir the microwave by being rotated due to the flow of the gas in the process chamber 5. That is, the microwave stirrer 95 is rotated using the flow of the gas in the process chamber 5 and thereby stirs the microwave. Therefore, according to the present embodiments, it is possible to reliably stir the microwave, and it is possible to stir the microwave without separately preparing the drive source (for example, the electric motor) for stirring the microwave.
(b) According to the present embodiments, the microwave stirrer 95 is rotated due to the flow of the gas exhausted through the exhauster 10. Therefore, according to the present embodiments, by utilizing the flow of the gas exhausted through the exhauster 10, it is possible to prevent (or suppress) the particles and the like from diffusing into the process chamber 5. Thus, it is possible to preferably prevent (or suppress) the productivity of the substrate processing on the wafer 2 from deteriorating.
(c) According to the present embodiments, the exhaust port 11A of the exhauster 10 includes the plurality of exhaust holes 110A, and the rotating shaft 95B of the microwave stirrer 95 is attached to one of the plurality of exhaust holes 110A. Therefore, according to the present embodiments, since the microwave stirrer 95 is installed using one of the plurality of exhaust holes 110A included in the exhaust port 11A of the multi-hole structure, it is possible to stir the microwave without making the major structural changes to a configuration of the exhauster 10 such as the exhaust port 11A, and it is also possible to prevent (or suppress) the airtightness within the process chamber 5 including the exhaust pipe 11 from being damaged. Thus, it is possible to preferably prevent (or suppress) the productivity of the substrate processing on the wafer 2 from deteriorating.

### (4) Modified Examples

While the technique of the present disclosure is described in detail by way of the embodiments described above, the technique of the present disclosure is not limited thereto. The technique of the present disclosure may be modified in various ways without departing from the scope thereof.

For example, the embodiments described above are described by way of an example in which the amorphous silicon film formed on the wafer 2 is modified into the polysilicon film by performing the substrate processing. However, the technique of the present disclosure is not limited thereto. For example, the technique of the present disclosure may be applied to modify a film formed on the surface of the wafer 2 by supplying a gas containing at least one among oxygen (O), nitrogen (N), carbon (C) and hydrogen (H). For example, when a hafnium oxide film (HfₓO_{y} film) serving as a high dielectric film is formed on the wafer 2, by supplying the microwave to heat the wafer 2 while supplying a gas containing oxygen, it is possible to supplement a deficient oxygen in the hafnium oxide film, and it is also possible to improve characteristics of the high dielectric film. While the hafnium oxide film is mentioned above as an example, the technique of the present disclosure is not limited thereto. For example, the technique of the present disclosure may be preferably applied to modify a metal-based oxide film, that is, an oxide film containing at least one metal element among aluminum (Al), titanium (Ti), zirconium (Zr), tantalum (Ta), niobium (Nb), lanthanum (La), cerium (Ce), yttrium (Y), barium (Ba), strontium (Sr), calcium (Ca), lead (Pb), molybdenum (Mo) and tungsten (W). That is, the substrate processing described above may be preferably applied to modify a film formed on the wafer 2 such as a TiOCN film, a TiOC film, a TiON film, a TiO film, a ZrOCN film, a ZrOC film, a ZrON film, a ZrO film, a HfOCN film, a HfOC film, a HfON film, a HfO film, a TaOCN film, a TaOC film, a TaON film, a TaO film, a NbOCN film, a NbOC film, a NbON film, a NbO film, an AlOCN film, an AlOC film, an AlON film, an AlO film, a MoOCN film, a MoOC film, a MoON film, a MoO film, a WOCN film, a WOC film, a WON film and a WO film. Further, without being limited to the high dielectric film, the technique of the present disclosure may be applied to heat a film containing silicon as a primary element (main element) and doped with impurities. A silicon-based film such as a silicon nitride film (SiN film), a silicon oxide film (SiO film), a silicon oxycarbide film (SiOC film), a silicon oxycarbonitride film (SiOCN film) and a silicon oxynitride film (SiON film) may be used as the above-mentioned film containing silicon as the primary element. For example, the impurities may include at least one element among boron (B), carbon (C), nitrogen (N), aluminum (Al), phosphorus (P), gallium (Ga) and arsenic (As). In addition, the technique of the present disclosure may be applied to process a photoresist film based on at least one photoresist among methyl methacrylate resin (polymethyl methacrylate, PMMA), epoxy resin, novolac resin or polyvinyl phenyl resin.

For example, the embodiments described above are described by way of an example in which the modification process is performed as the process performed in the substrate processing. However, the technique of the present disclosure is not limited thereto. For example, the technique of the present disclosure may be applied to other processes of the substrate processing such as the oxidation process, the diffusion process, the etching process, the pre-cleaning process, the chamber cleaning process and the film forming process as long as the microwave heating is performed in such processes.

For example, the embodiments described above are described by way of an example in which the substrate processing is performed as a part of the manufacturing process of the semiconductor device. However, the technique of the present disclosure is not limited thereto. For example, the technique of the present disclosure may be applied to other substrate processing such as a patterning process of a manufacturing process of a liquid crystal panel, a patterning process of a manufacturing process of a solar cell and a patterning process of a manufacturing process of a power device.

According to some embodiments of the present disclosure, it is possible to prevent the uniformity of the temperature distribution on the substrate from deteriorating when the microwave heating is performed, and thereby it is possible to prevent a deterioration in the productivity of the substrate processing from deteriorating.

What is claimed is:

1. A substrate processing apparatus comprising:
a process chamber in which a substrate is processed;
a gas supplier configured to supply a gas into the process chamber;
a microwave supplier configured to supply a microwave into the process chamber; and
a microwave stirrer configured to stir the microwave by being rotated due to a flow of the gas in the process chamber.

2. The substrate processing apparatus of claim 1, further comprising
a gas exhauster through which the gas is exhausted from the process chamber.

3. The substrate processing apparatus of claim 2, wherein the microwave stirrer is provided at the gas exhauster.

4. The substrate processing apparatus of claim 2, wherein the microwave stirrer is configured to be rotated due to the flow of the gas exhausted from the process chamber.

5. The substrate processing apparatus of claim 2, wherein the gas exhauster comprises a plurality of exhaust holes.

6. The substrate processing apparatus of claim 5, wherein the microwave stirrer comprises:
a blade configured to stir the microwave; and
a rotating shaft configured to rotate the blade.

7. The substrate processing apparatus of claim 6, wherein the microwave stirrer is configured such that the rotating shaft is attached to one of the plurality of exhaust holes.

8. The substrate processing apparatus of claim 6, wherein the blade is of a propeller shape.

9. The substrate processing apparatus of claim 6, wherein the blade is made of a high dielectric material whose dielectric loss is low.

10. The substrate processing apparatus of claim 9, wherein the high dielectric material whose dielectric loss is low comprises a metal material or a ceramic material.

11. The substrate processing apparatus of claim 6, further comprising
a detection sensor provided at the rotating shaft and configured to be capable of detecting whether or not the blade and the rotating shaft are being rotated.

12. The substrate processing apparatus of claim 11, further comprising
a controller configured to be capable of controlling the gas supplier to increase a supply flow rate of the gas when the detection sensor detects that the blade and the rotating shaft are not being rotated.

13. The substrate processing apparatus of claim 2, wherein the gas exhauster is provided at an upper portion of the process chamber.

14. The substrate processing apparatus of claim 2, further comprising:
one or more gas exhausters through which the gas is exhausted from the process chamber.

15. The substrate processing apparatus of claim 13, wherein the gas exhauster is provided at four corners of the upper portion of the process chamber.

16. The substrate processing apparatus of claim 1, wherein the gas is supplied to cool the substrate.

17. The substrate processing apparatus of claim 1, further comprising
a substrate retainer configured to accommodate the substrate.

18. The substrate processing apparatus of claim 17, wherein the substrate retainer is configured to accommodate one or more substrates in addition to the substrate.

19. A substrate processing method comprising:
(a) supplying a gas into a process chamber in which a substrate is processed;
(b) exhausting the gas from the process chamber;
(c) supplying a microwave into the process chamber; and
(d) stirring the microwave with a microwave stirrer being rotated due to a flow of the gas in the process chamber.

20. A method of manufacturing a semiconductor device, comprising the substrate processing method of claim 19.

21. A non-transitory computer-readable recording medium storing a program that causes a substrate processing apparatus, by a computer, to perform:
(a) supplying a gas into a process chamber in which a substrate is processed;
(b) exhausting the gas from the process chamber;
(c) supplying a microwave into the process chamber; and
(d) stirring the microwave with a microwave stirrer being rotated due to a flow of the gas in the process chamber.
